(19) United States
(12) Patent Application Publication
(10) Pub. No.: US 2026/0223640 A1
(43) Pub. Date: Jul. 30, 2026

(54) PROCESSING APPARATUS, CHIP MANUFACTURING METHOD, AND PROCESSING METHOD

(71) Applicant: DISCO CORPORATION, Tokyo (JP)

(72) Inventor: Naoko Yamamoto, Tokyo (JP)

(21) Appl. No.: 19/444,860

(22) Filed: Jan. 9, 2026

(30) Foreign Application Priority Data
Jan. 29, 2025 (JP) 2025-012776

(51) Int. Cl. H10P 72/76; H10P 54/20; H10P 72/00

(52) U.S. Cl. CPC H10P 72/7618; H10P 54/20; H10P 72/0408; H10P 72/0428

(57) ABSTRACT

A processing apparatus including a holding portion with a holding surface to hold a workpiece; a processing unit for processing the workpiece; a first moving portion for relatively moving a processing point of the processing unit and the holding portion in a first direction; a second moving portion for relatively moving the processing point and the holding portion in a second direction that intersects the first direction; an attaching roller extending along the holding surface; a third moving portion for relatively moving the attaching roller and the holding portion; a reinforcing member supporting portion for supporting a reinforcing member; and a control portion for controlling at least the third moving portion and for generating a reinforcing unit in which the reinforcing member supported by the reinforcing member supporting portion and the workpiece held on the holding portion are integrated by the attaching roller.

### BACKGROUND

### Technical Field

The present disclosure relates to a processing apparatus for processing a plate-like workpiece, a method for manufacturing a chip by dividing a plate-like workpiece along division lines, and a method for processing a plate-like workpiece.

### Description of the Related Art

On a front face of a wafer, a chip region where a plurality of chips are formed, and an outer peripheral surplus region which surrounds the chip region, are disposed. Each chip in the chip region is sectioned by a plurality of division lines.

The wafer may be divided into individual chips by a cutting apparatus including an annular cutting blade which rotates at high-speed. For example, in the case of a wafer dividing method disclosed in JP 2015-228475 A, a first adhesive tape is attached to a front face of a wafer, then half cut grooves are formed on a rear face of the wafer by allowing a cutting blade of a first cutting apparatus to cut along division lines from the rear face of the wafer, and then a first adhesive tape is attached to the rear face of the wafer, and the first adhesive tape on the front face of the wafer is peeled off. Then the wafer is divided into individual chips by allowing a cutting blade of a second cutting apparatus to cut along the division lines from the front face of the wafer. In the case of this wafer dividing method, the cutting blade is not allowed to cut into the first or second adhesive tape, hence an effect of preventing contamination of the wafer by generated processing chips, which include the adhesive of the first and second adhesive tapes, can be elicited.

### SUMMARY

In the abovementioned wafer dividing method, however, the strength of the wafer is dropped due to forming the half cut grooves along the division lines, which may cause damage to the wafer while handling the wafer after the half cut grooves are formed along the division lines. For example, after the half cut grooves are formed on the rear face of the wafer by the first cutting apparatus, the wafer may be damaged while the wafer is conveyed from the first cutting apparatus to the second cutting apparatus.

It is an object of the present disclosure to provide a processing apparatus, a chip manufacturing method, and a processing method, which can prevent damage to a workpiece while handling the processed workpiece.

The present disclosure provides a following processing apparatus to solve the abovementioned problem, that is, a processing apparatus for processing a plate-like workpiece, the apparatus including: a holding portion including a holding surface to hold the workpiece; a processing unit configured to process the workpiece held on the holding portion; a first moving portion configured to relatively move a processing point of the processing unit and the holding portion in a first direction along the holding surface; a second moving portion configured to relatively move the processing point of the processing unit and the holding portion in a second direction that intersects the first direction and is along the holding surface; an attaching roller extending along the holding surface; a third moving portion configured to relatively move the attaching roller and the holding portion; a reinforcing member supporting portion configured to support a reinforcing member such that a principal surface of the reinforcing member faces the holding surface of the holding potion; and a control portion configured to control at least the third moving portion, and to generate a reinforcing unit in which the reinforcing member supported by the reinforcing member supporting portion and the workpiece held on the holding portion are integrated by the attaching roller.

It is preferable that the processing apparatus further includes a reversing portion configured to reverse the workpiece, the reinforcing member or the reinforcing unit. It is also preferable that the processing apparatus further includes: a mounting portion on which a container for housing the workpiece, the reinforcing member or the reinforcing unit, is mounted; and a conveying portion configured to convey the workpiece, the reinforcing member or the reinforcing unit between the mounting portion and the holding portion.

It is preferable that the processing unit is a laser beam applying unit including a laser oscillator for oscillating a laser beam, and a condensing lens for condensing the laser beam oscillated by the laser oscillator.

It is preferable that the processing unit is a cutting unit including a spindle configured to be rotatable around a rotation shaft line, and a cutting blade attached to the spindle. The processing unit may further include: a cleaning portion configured to supply cleaning fluid to the workpiece held on the holding portion; and a drying portion configured to supply compressed air to the workpiece held on the holding portion.

The present disclosure also provides a following chip manufacturing method to solve the abovementioned problem, that is, a chip manufacturing method for manufacturing chips by dividing a plate-like workpiece, where chip regions in which chips are formed are included and division lines for sectioning the chip lines are set, into individual chips along the division lines. This chip manufacturing method includes: forming a dividing start point along the division line on the workpiece while holding the workpiece on a holding portion; implementing reinforcement by fixing a reinforcing member on an exposed surface of the workpiece held on the holding portion after the forming of a dividing start point; and dividing the workpiece along the division line after the implementing of reinforcement.

It is preferable that a protective member is fixed to a first face of the workpiece, and in the implementing o reinforcement, the reinforcing member is fixed to a second face of the workpiece, the second face being an opposite side to the first face. It is also preferable that the method further includes separating the protective member from the workpiece after the implementing of reinforcement and before the dividing of the work piece.

The present disclosure also provides a following processing method to solve the abovementioned problem, that is, a processing method for processing a plate-like workpiece including: forming a dividing start point along a division line on a workpiece while holding the workpiece on a holding portion; and implementing reinforcement by fixing a reinforcing member on an exposed surface of the workpiece held on the holding portion after the forming of a dividing start point.

The processing apparatus of the present disclosure is a processing apparatus for processing a plate-like workpiece, the apparatus including: a holding portion including a holding surface to hold the workpiece; a processing unit configured to process the workpiece held on the holding portion; a first moving portion configured to relatively move a processing point of the processing unit and the holding portion in a first direction along the holding surface; a second moving portion configured to relatively move the processing point of the processing unit and the holding portion in a second direction that intersects the first direction and is along the holding surface; an attaching roller extending along the holding surface; a third moving portion configured to relatively move the attaching roller and the holding portion; a reinforcing member supporting portion configured to support a reinforcing member such that a principal surface of the reinforcing member faces the holding surface of the holding potion; and a control portion configured to control at least the third moving portion, and to generate a reinforcing unit in which the reinforcing member supported by the reinforcing member supporting portion and the workpiece held on the holding portion are integrated by the attaching roller.

Therefore, damage to a processed workpiece while handling the workpiece can be prevented.

The chip manufacturing method of the present disclosure is a chip manufacturing method for manufacturing chips by dividing a plate-like workpiece, where chips regions in which chips are formed are included and division lines for sectioning the chip lines are set, into individual chips along the division lines. This chip manufacturing method includes: forming a dividing start point along the division line on the workpiece while holding the workpiece on a holding portion; implementing reinforcement by fixing a reinforcing member on an exposed surface of the workpiece held on the holding portion after the forming of a dividing start point; and dividing the workpiece along the division line after the implementing of reinforcement. Therefore, damage to a processed workpiece while handling the workpiece can be prevented.

The processing method of the present disclosure is a processing method for processing a plate-like workpiece, the method including: forming step of forming a dividing start point along a division line on a workpiece while holding the workpiece on a holding portion; and implementing reinforcement by fixing a reinforcing member on an exposed surface of the workpiece held on the holding portion after the forming of a dividing start point. Therefore, damage to a processed workpiece while handling the workpiece can be prevented.

### BRIEF DESCRIPTION OF THE DRAWINGS

FIG. 1 is a perspective view of a processing apparatus of the present disclosure;

FIG. 2 is a perspective view of a holding portion illustrated in FIG. 1 (in a state where a bellows cover is removed);

FIG. 3 is a perspective view of a processing unit illustrated in FIG. 1;

FIG. 4 is a perspective view of an attaching roller and the like illustrated in FIG. 1;

FIG. 5 is a perspective view of a reinforcing member supporting portion illustrated in FIG. 1;

FIG. 6 is a perspective view of a mounting portion illustrated in FIG. 1;

FIG. 7 is a perspective view of a second conveying portion illustrated in FIG. 1;

FIG. 8 is a perspective view of a wafer;

FIG. 9 is a perspective view of a frame unit;

FIG. 10 is a perspective view of a reinforcing member;

FIG. 11 is a perspective view of the reinforcing member supported by a frame;

FIG. 12 is a schematic diagram depicting reinforcing in a case of fixing the reinforcing member, which is supported by supporting rails of the reinforcing member supporting portion, to the wafer held on the holding portion;

FIG. 13 is a schematic diagram depicting the reinforcing in a case of fixing the reinforcing member, which is supported by clamps used as the reinforcing member supporting portion, to the wafer held on the holding portion;

FIG. 14 is a schematic diagram depicting the reinforcing in a case of fixing the reinforcing member, which is supported by supporting rails of the reinforcing member supporting portion, to the wafer in the frame unit held on the holding portion;

FIG. 15 is a schematic diagram depicting the reinforcing in a case of fixing the reinforcing member, which is supported by clamps used as the reinforcing member support portion, to the wafer in the frame unit held on the holding portion;

FIG. 16 is a schematic diagram depicting a state where an attaching roller is raised after the reinforcing;

FIG. 17 is a schematic diagram depicting a state where an arm of a first receiving portion is reversed and lowered after the state illustrated in FIG. 16, and the reinforcing unit is held by suction using suction pads of the first receiving portion;

FIG. 18 is a schematic diagram depicting a state where the arm of the first receiving portion is raised after the state illustrated in FIG. 17;

FIG. 19 is a schematic diagram depicting a state where the arm of the first receiving portion is reversed after the state illustrated in FIG. 18;

FIG. 20 is a schematic diagram depicting a state where the first receiving portion transfers the reinforcing unit to a second receiving portion after the state illustrated in FIG. 19;

FIG. 21 is a schematic diagram depicting a state where the arm of the second receiving portion is raised after the state illustrated in FIG. 20;

FIG. 22 is a schematic diagram depicting a state where the supporting rails are located below the second receiving portion after the state illustrated in FIG. 21;

FIG. 23 is a schematic diagram depicting a state where the second receiving portion transfers the reinforcing unit to the supporting rails after the state illustrated in FIG. 22;

FIG. 24 is a schematic diagram depicting dividing; and

FIG. 25 is a schematic diagram in a case where the attaching roller is supported by the arm of the second receiving portion.

### DESCRIPTION OF THE PREFERRED EMBODIMENTS

Embodiments of the processing apparatus, the chip manufacturing method and the processing method of the present disclosure will now be disclosed with reference to the drawings.

### Processing Apparatus 2

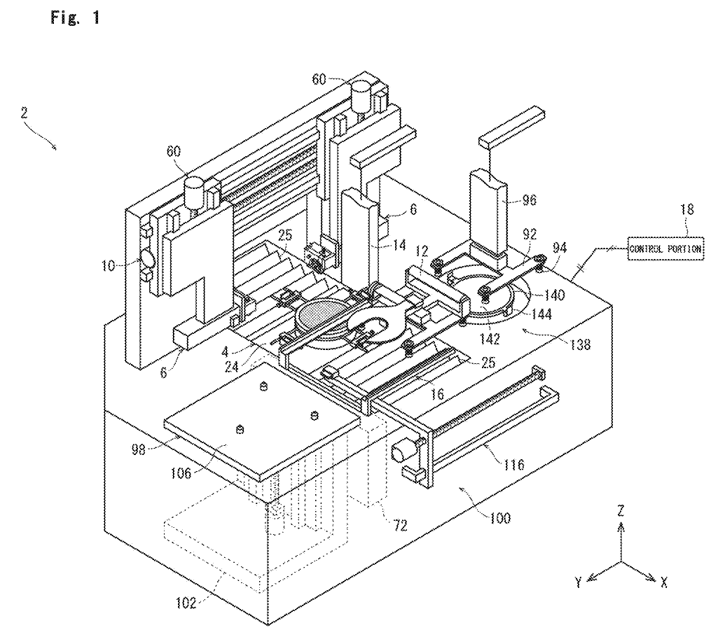

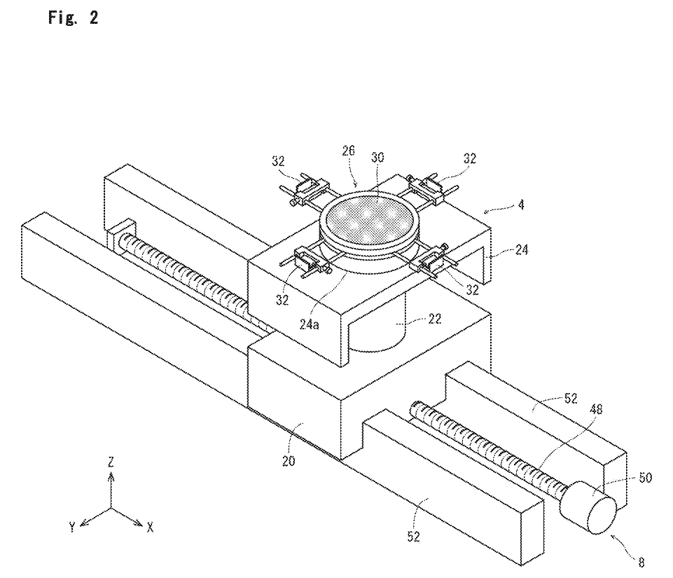

A processing apparatus 2, denoted with a reference number “2” in FIG. 1, includes a holding portion 4, a processing unit 6, a first moving portion 8 (see FIG. 2), a second moving portion 10, an attaching roller 12, a third moving portion 14, reinforcing member supporting portion 16, and a control portion 18.

### Holding Portion 4 of Processing Apparatus 2

The holding portion 4 includes a holding surface on which a plate-like workpiece is held. As illustrated in FIG. 2, the holding portion 4 includes an X axis movable member 20 which is disposed to be movable in an X axis direction (indicated by arrow X), a support 22 which is fixed to an upper face of the X axis movable member 20, and a cover plate 24 which is fixed to the upper end of the support 22. A bellows cover 25 is disposed on both sides of the cover plate 24 in the X axis direction (see FIG. 1). As illustrated in FIG. 2, a circular opening 24a is formed on the cover plate 24, and a chuck table 26, which extends upward through the circular opening 24a, is rotatably supported at the upper end of the support 22. The chuck table 26 is rotated by a motor (not illustrated) around a rotation shaft line, which extends in the Z axis direction through the center of the chuck table 26. A Y axis direction (indicated by arrow Y) is a direction which orthogonally intersects with the X axis direction, and a Z axis direction (indicated by arrow Z) is a vertical direction which orthogonally intersects with the X axis direction and the Y axis direction. An XY plane specified by the X axis direction and the Y axis direction is substantially horizontal.

A disk-shaped suction chuck 30 is disposed at the upper end of the chuck table 26 of the holding portion 4. The suction chuck 30 is made of a porous member (e.g. porous ceramic), and is connected to a suction pump (not illustrated). The holding portion 4 generates a suction force on the upper face of the suction chuck 30 using the suction pump, and holds by suction a workpiece placed on the upper face of the chuck table 26. In this way, in the holding portion 4 of this embodiment, the upper face of the suction chuck 30 of the chuck table 26 is a holding surface to hold the workpiece. The holding surface of the holding portion 4 is located on the XY plane.

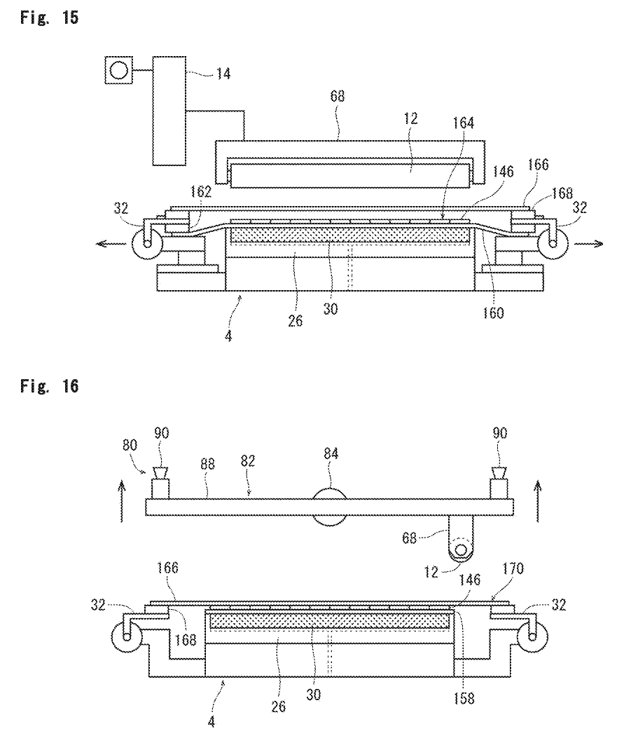

At the periphery of the chuck table 26 of the holding portion 4, a plurality of (four in this example) clamps 32, to hold a later mentioned frame, are disposed at intervals in the circumferential direction. Each of the clamps 32 is set at a position of holding the frame (position illustrated in FIG. 15), and a position of releasing the holding of the frame (position illustrated in FIG. 2), using a clamp activating portion (not illustrated), such as an air-driven actuator. Upper end faces of the plurality of clamps 32 that are set to the position of holding the frame are on the same XY plane, which is substantially parallel with the holding surface of the holding portion 4. Therefore, the reinforcing member can be supported by the upper end faces of the clamps 32 that are set in the holding position, such that the principal surface of the reinforcing member faces the holding surface of the holding portion 4. In other words, the plurality of clamps 32 can function as a reinforcing member supporting portion such that the principal surface of the reinforcing member faces the holding surface of the holding portion 4. The processing apparatus 2 of this embodiment, however, includes a reinforcing member supporting portion 16 other than clamps 32.

### Processing Unit 6 of Processing Apparatus 2

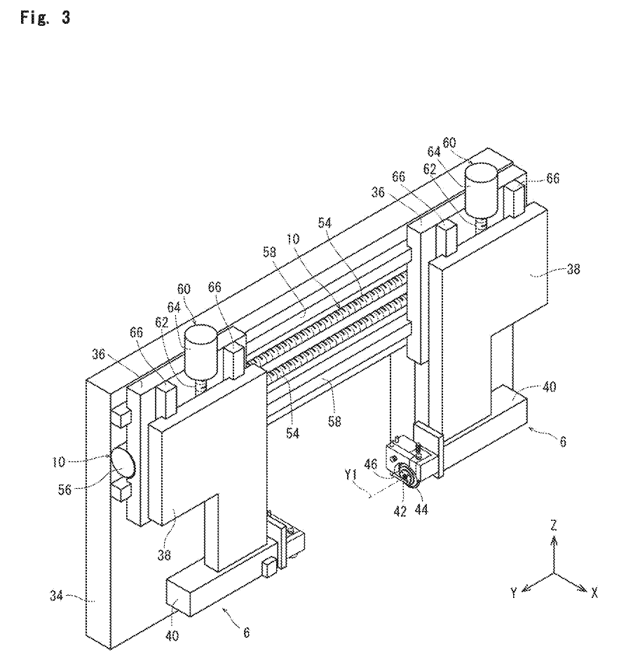

The processing unit 6 processes a workpiece held on the holding portion 4. The processing unit 6 of this embodiment is a cutting unit which performs cutting processing on a workpiece. As illustrated in FIG. 3, in this embodiment, a pair of processing unit 6 are disposed at an interval in the Y axis direction. The pair of processing units 6 are attached to a gate-shaped supporting member 34 which is disposed extending over a track of the holding portion 4. In the processing apparatus 2 of this embodiment, the pair of processing units 6 are disposed such that the respective cutting blades face each other, whereby the workpiece held on the holding portion 4 can be simultaneously cut using the pair of cutting blades. The member of processing units 6 may be one.

Each processing unit 6 includes: a Y axis movable member 36 which is supported by the supporting member 34 to be movable in the Y axis direction; a Z axis movable member 38 which is supported by the Y axis movable member 36 to be movable in the Z axis direction; and a spindle housing 40 which is fixed to the lower end of the Z axis movable member 38. In the spindle housing 40, a spindle 42 is supported to be rotatable around the rotation shaft line Y1, which extends along the Y axis direction, and a motor (not illustrated) to rotate the spindle 42 is housed. An annular cutting blade 44, to cut the workpiece, is fixed to the front end of the spindle 42, and the cutting blade 44 rotates together with the rotation of the spindle 42 rotated by the motor. Thus each processing unit 6 of this embodiment includes the spindle 42 which is rotatable around the rotation shaft line Y1, and the cutting blade 44 attached to the spindle 42. Further, a cutting water nozzle 46, which injects cutting water (e.g. pure water) to a point where the cutting blade 44 performs cutting processing on the workpiece (processing point), is attached to the front end of the spindle housing 40.

Although not illustrated, the processing unit 6 may also include a cleaning portion which supplies cleaning fluid (e.g. pure water, a fluid mixture of pure water and compressed air) to the workpiece held on the holding portion 4, and a drying portion which supplies compressed air to the workpiece held on the holding portion 4. The cleaning portion includes a nozzle disposed adjacent to the holding portion 4, and a cleaning fluid supply source which supplies the cleaning fluid to the nozzle. The drying portion includes a nozzle disposed adjacent to the holding portion 4, and a compressed air supply source which supplies compressed air to the nozzle.

In a case where the processing unit 6 includes the cleaning portion and the drying portion, it is possible that after the processing unit 6 performs the cutting processing on a workpiece held on the holding portion 4, the workpiece can be cleaned with the cleaning fluid supplied to the workpiece held on the holding portion 4 through the nozzle of the cleaning portion, and then the workpiece can be dried with the compressed air supplied to the workpiece held on the holding portion 4 through the nozzle of the drying portion. In other words, it is not necessary to move the workpiece from the holding portion 4, and the workpiece can be cleaned and dried in the state of being held on the holding portion 4.

The processing unit 6 is not limited to the abovementioned cutting unit. For example the processing unit 6 may be a laser beam applying unit including a laser oscillator which oscillates a laser beam, and a condensing lens which condenses the laser beam oscillated by the laser oscillator.

### First Moving Portion 8 of Processing Apparatus 2

The first moving portion 8 relatively moves the processing point of the processing unit 6 and the holding portion 4 in a first direction (X axis direction) along the holding surface of the holding portion 4. As illustrated in FIG. 2, the first moving portion 8 of this embodiment includes: a ball screw 48 which is connected to the X axis movable member 20 and extends in the X axis direction; a motor 50 which rotates the ball screw 48; and guide rails 52 which extend in the X axis direction along the ball screw 48. The guide rails 52 slidably support the X axis movable member 20. The first moving portion 8 converts the rotary motion of the motor 50 into the linear motion using the ball screw 48, transfers the linear motion to the X axis movable member 20, and moves the X axis movable member 20 along the guide rails 52. Thereby the holding portion 4 moves to the processing point of the processing unit 6 in the first direction (X axis direction) along the holding surface. Conversely, the first moving portion 8 may move the processing point of the processing unit 6 to the holding portion 4 in the X axis direction.

### Second Moving Portion 10 of Processing Apparatus 2

The second moving portion 10 relatively moves the processing point of the processing unit 6 and the holding portion 4 in a second direction (Y axis direction), which intersects the first direction (X axis direction), along the holding surface of the holding portion 4. As illustrated in FIG. 3, the second moving portion 10 includes: a ball screw 54 which is connected to the Y axis movable member 36 and extends in the Y axis direction; a motor 56 which rotates the ball screw 54; and guide rails 58 which extend in the Y axis direction along the ball screw 54. The guide rails 58 slidably support the Y axis movable member 36. The second moving portion 10 converts the rotary motion of the motor 56 into the linear motion using the ball screw 54, transfers the linear motion to the Y axis movable member 36, and moves the Y axis movable member 36 along the guide rails 58. Thereby the processing point of the processing unit 6 moves to the holding portion 4 in the second direction (Y axis direction), which intersects the first direction (X axis direction) and along the holding surface. Conversely, the second moving portion 10 may move the holding portion 4 to the processing point of the processing unit 6 in the Y axis direction.

### Z Axis Moving Portion 60 to Move Processing Unit 6 in Z Axis

The processing apparatus 2 of this embodiment further includes a Z axis moving portion 60 which moves the processing point of the processing unit 6 to the holding portion 4 in the Z axis direction. As illustrated in FIG. 3, the Z axis moving portion 60 includes: a ball screw 62 which is connected to the Z axis movable member 38 and extends in the Z axis direction; a motor 64 which rotates the ball screw 62; and guide rails 66 which extend in the Z axis direction along the ball screw 62. The guide rails 66 slidably supports the Z axis movable member 38. The Z axis moving portion 60 converts the rotary motion of the motor 64 into the linear motion using the ball screw 62, transfers the linear motion to the Z axis movable member 38, and moves the Z axis movable member 38 along the guide rails 66. Thereby the processing point of the processing unit 6 moves to the holding portion 4 in the Z axis direction.

### Attaching Roller 12 of Processing Apparatus 2

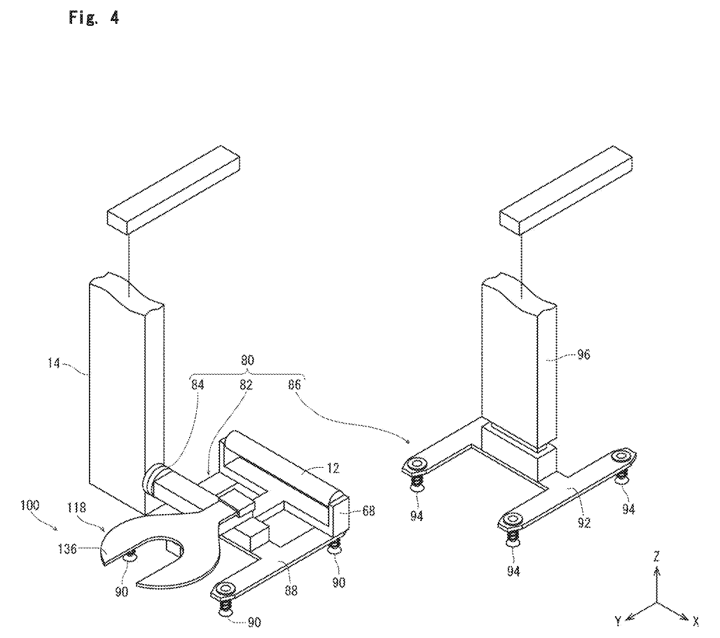

The attaching roller 12 is disposed extending along the holding surface of the holding portion 4. As illustrated in FIG. 4, the attaching roller 12 extends along the X axis direction, and is supported by a bracket 68 to be rotatable around the rotation shaft line which extends in the X axis direction penetrating the center of the attaching roller 12. The attaching roller 12 is a roller to press and attach the processed workpiece, which is held on the holding portion 4 to a reinforcing member. The reinforcing member will be described later. If the reinforcing member is a thermocompression sheet, a heater (not illustrated), to heat the outer peripheral surface of the attaching roller 12 to a temperature around melting point of the thermocompression sheet, is disposed at the attaching roller 12.

### Third Moving Portion 14 of Processing Apparatus 2

The third moving portion 14 relatively moves the attaching roller 12 and the holding portion 4. As illustrated in FIG. 4, the third moving portion 14 of this embodiment moves the bracket 68, which supports the attaching roller 12, to the holding portion 4 in the Y axis direction and the Z axis direction. For example, the third moving portion 14 may be an air-driven actuator or a ball screw type actuator.

### Reinforcing Member Supporting Portion 16 of Processing Apparatus 2

The reinforcing member supporting portion 16 supports the reinforcing member such that the principal surface of the reinforcing member faces the holding surface of the holding portion 4. As illustrated in FIG. 5, the reinforcing member supporting portion 16 includes: a pair of supporting rails 70 which are disposed at an interval in the X axis direction; and a supporting rail moving portion 72 which adjusts the interval of the pair of supporting rails 70 in the X axis direction, and moves (elevates) the pair of supporting rails 70 in the Z axis direction. Each supporting rail 70 includes a supporting plate 74 which extends in the Y axis direction, a side wall 76 which extends upward from an end of the supporting plate 74 on one side end portion in the X axis direction; and a connection member 78 which extends downward from an end of the supporting plate 74 on one side end portion in the Y axis direction. The supporting plate 74 and the side wall 76 of each supporting rail 70 are disposed on a track of the holding portion 4 (see FIG. 1). The connection member 78 of each supporting rail 70 is connected to the supporting rail moving portion 72. The supporting rail moving portion 72 may be an air-driven actuator or a ball screw type actuator, for example.

### Control Portion 18 of Processing Apparatus 2

The control portion 18 controls at least the third moving portion 14, and generates a reinforcing unit where the reinforcing member supported by the reinforcing member supporting portion 16, and a processed workpiece held on the holding portion 4, are integrated by the attaching roller 12. The control portion 18 is a computer which includes a processor and memory. The control portion 18 may be configured to control not only the activation of the third moving portion 14, but also activation of a part or all of the processing apparatus 2 (e.g. activation of first and second moving portions 8 and 10).

### Reversing Portion 80 of Processing Apparatus 2

The processing apparatus 2 of this embodiment further includes a reversing portion 80 which reverses the workpiece, a reinforcing member or a reinforcement unit (may be referred to as “workpiece or the like” herein below). As illustrated in FIG. 4, the reversing portion 80 includes: a first receiving portion 82 which receives the workpiece or the like from the holding portion 4; an actuator 84 which reverses the first receiving portion 82 which received the workpiece or the like; and a second receiving portion 86 which receives the workpiece or the like from the reversed first receiving portion 82.

### First Receiving Portion 82 of Reversing Portion 80

The first receiving portion 82 includes: an arm 88 which is an H-shaped plate attached to the bracket 68 supporting the attaching roller 12; and a plurality of (four in this embodiment) suction pads 90 which are disposed on the lower face of the arm 88. Each suction pad 90 is connected to a suction pump (not illustrated). The first receiving portion 82 generates a suction force on the suction pads 90 using the suction pump, and receives the workpiece or the like, which is held on the holding portion 4 from the holding portion 4, by suction using the suction pads 90.

### Actuator 84 of Reversing Portion 80

The actuator 84 is connected to the bracket 68 supporting the attaching roller 12, and reverses the bracket 68 around the rotation shaft line which extends in the X axis direction. Thereby the first receiving portion 82 which received the workpiece or the like is reversed, and the workpiece or the like is positioned above the first receiving portion 82. The actuator 84 here may be an air-driven rotary actuator (rotary cylinder) or an electric motor.

### Second Receiving Portion 86 of Reversing Portion 80

The second receiving portion 86 includes: an arm 92 which is an H-shaped plate; a plurality of (four in this embodiment) suction pads 94 which are disposed on the lower face of the arm 92; and an arm moving portion 96 which moves the arm 92 in the X axis direction and the Z axis direction. Each suction pad 94 is connected to a suction pump (not illustrated). The arm moving portion 96 may be an air-driven actuator or a ball screw type actuator, for example. The second receiving portion 86 moves the arm 92 using the arm moving portion 96, and allows the lower end of each suction pad 94 to contact with the upper face of the workpiece or the like positioned above the first receiving portion 82. Further, the second receiving portion 86 generates a suction force on the suction pads 94 using the suction pump, and receives the workpiece or the like being held on the first receiving portion 82 from the first receiving portion 82 by suctioning and holding using the suction pads 94.

As illustrated in FIG. 1, the processing apparatus 2 of this embodiment further includes: a mounting portion 98 on which a container to house the workpiece, reinforcing member or reinforcing unit is mounted; and a conveying portion 100 which conveys the workpiece, reinforcing member or reinforcing unit between the mounting portion 98 and the holding portion 4.

### Mounting Portion 98 of Processing Apparatus 2

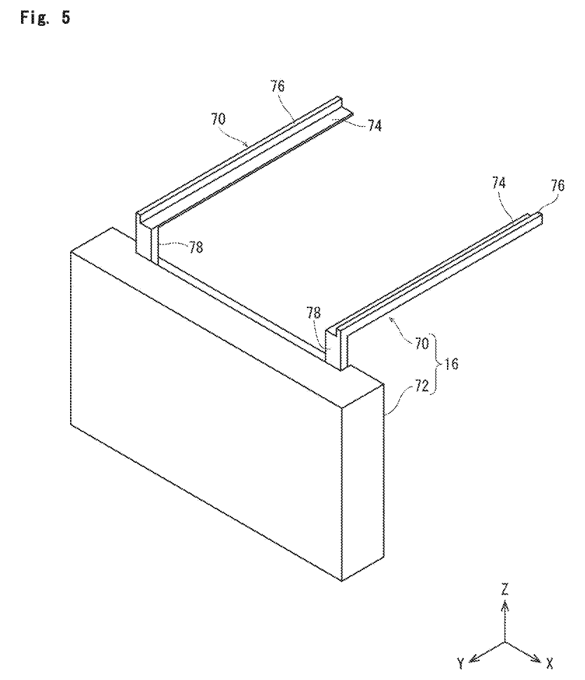

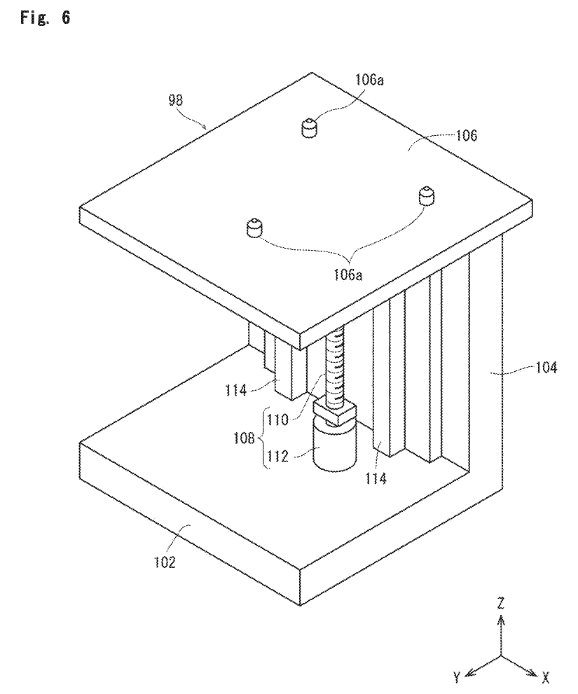

As illustrated in FIG. 6, the mounting portion 98 includes: a base plate 102; a vertical plate 104 which extends upward from the end of the base plate 102; a mounting table 106 which is movable (liftably) supported on the vertical plate 104 in the Z axis direction; and a table moving portion 108 which moves the mounting table 106 in the Z axis direction. The mounting portion 98 is disposed next to the reinforcing member supporting portion 16 at an interval in the Y axis direction, and the position of the mounting portion 98 in the X axis direction is approximately aligned with the position of the reinforcing member supporting portion 16 in the X axis direction.

### Mounting Table 106 of Mounting Portion 98

On the upper face of the mounting table 106, a plurality of (three in this embodiment) protrusions 106a are disposed to place a container (not illustrated) housing the workpiece or the like at a predetermined position. On the upper surface of the mounting table 106, a single container housing both the workpiece and the reinforcing member may be mounted or a first container housing the workpiece and a second container housing the reinforcing member may be mounted in a stacked state. The workpiece or the like is housed in the container maintaining an interval in the vertical direction.

### Table Moving Portion 108 of Mounting Portion 98

The table moving portion 108 includes: a ball screw 110 which is connected to the mounting table 106 and extends in the Z axis direction; a motor 112 which rotates the ball screw 110; and guide rails 114 which extend in the Z axis direction along the ball screw 110. The guide rails 114 slidably support the mounting table 106. The table moving portion 108 converts the rotary motion of the motor 112 into linear motion using the ball screw 110, and transfers the linear motion to the mounting table 106, whereby the mounting table 106 is moved along the guide rails 114.

### Conveying Portion 100 of Processing Apparatus 2

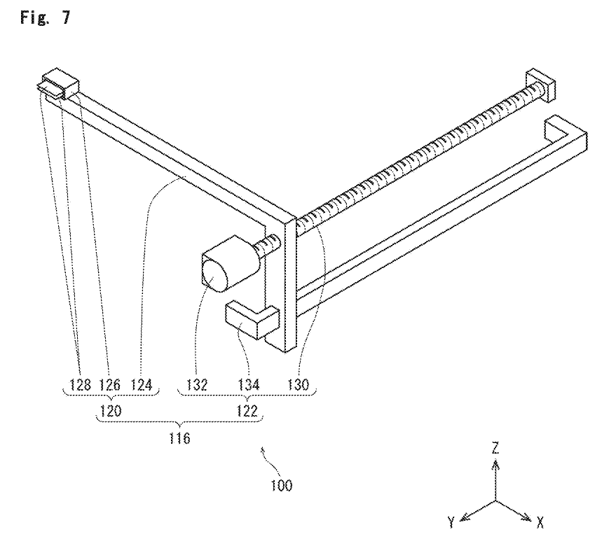

The conveying portion 100 includes: a first conveying portion 116 (see FIG. 7) which conveys a workpiece or the like supported by a later mentioned frame; and a second conveying portion 118 (see FIG. 4) which conveys a workpiece or the like not supported by the later mentioned frame.

### First Conveying Portion 116 of Conveying Portion 100

As illustrated in FIG. 7, the first conveying portion 116 includes: a conveying holding portion 120 which holds a workpiece or the like; and a Y axis moving portion 122 which moves the conveying holding portion 120 in the Y axis direction.

### Conveying Holding Portion 120 of First Conveying Portion 116

The conveying holding portion 120 includes: an L-shaped bracket 124; a drive portion 126 which is disposed at the front end of the bracket 124; and a pair of holding pieces 128 disposed at the drive portion 126. The pair of holding pieces 128 are disposed at an interval in the Z axis direction. The drive portion 126 includes an air-driven actuator (not illustrated) which adjusts the interval of the pair of holding pieces 128 in the Z axis direction. The conveying holding portion 120 holds a later mentioned frame supporting the workpiece or the like, by clamping the frame between the pair of holding pieces 128.

### Y Axis Moving Portion 122 of First Conveying Portion 116

The Y axis moving portion 122 includes: a ball screw 130 which is connected to the bracket 124 of the conveying holding portion 120 and extends in the Y axis direction; a motor 132 which rotates the ball screw 130; and a guide rail 134 which extends in the Y axis direction along the ball screw 130. The guide rail 134 slidably supports the bracket 124. The Y axis moving portion 122 converts the rotary motion of the motor 132 into the linear motion using the ball screw 130, and transfers the linear motion to the bracket 124, whereby the conveying holding portion 120 is moved along the guide rail 134.

### Second Conveying Portion 118 of Conveying Portion 100

As illustrated in FIG. 4, the second conveying portion 118 is attached to the bracket 68 supporting the attaching roller 12. The second conveying portion 118 of this embodiment includes a conveying holding portion 136, which is a U-shaped plate. Although this is not illustrated, a plurality of suction holes (not illustrated) are formed at intervals on one side of the conveying holding portion 136, and the suction holes are connected to a suction pump. The second conveying portion 118 generates a suction force in the suction holes of the conveying holding portion 136 using the suction pump, and holds the workpiece or the like by suction using the conveying holding portion 136. Further, the second conveying portion 118 is moved in the Y axis direction and the Z axis direction by the third moving portion 14.

The conveying holding portion 136 of the second conveying portion 118 may be a Bernoulli pad. In other words, the conveying holding portion 136 may be a Bernoulli pad which generates negative pressure on one side of the conveying holding portion 136 based on the Bernoulli effect, by ejecting compressed air from one side of the conveying holding portion 136, and holds the workpiece or the like on one side of the conveying holding portion 136 by suction in a state where the conveying holding portion 136 and the workpiece or the like are not in contact.

### Cleaning Unit 138 of Processing Apparatus 2

The processing apparatus 2 further includes a cleaning unit 138 which cleans the processed workpiece. As illustrated in FIG. 1, the cleaning unit 138 of this embodiment is disposed next to the reinforcing member supporting portion 16 at an interval in the Y axis direction, and the position of the cleaning unit 138 in the X axis direction is approximately aligned with the position of the reinforcing member supporting portion 16 in the X axis direction. The cleaning unit 138 includes: a spinner table 140 which holds the workpiece; and a cleaning portion (not illustrated) which supplies cleaning fluid (e.g. pure water, fluid mixture of pure water and compressed air) to the workpiece held on the spinner table 140; and a drying portion (not illustrated) which supplies compressed air to the workpiece held on the spinner table 140.

### Spinner Table 140 of Cleaning Unit 138

A disk-shaped suction chuck 142 is disposed at the upper end of the spinner table 140. The suction chuck 142 is made of a porous member (e.g. porous ceramic), and is connected to a suction pump (not illustrated). The spinner table 140 generates a suction force on the upper face of the suction chuck 142 using the suction pump, so as to hold the workpiece placed on the upper face of the spinner table 140 by suction. At the periphery of the spinner table 140, a plurality of (four in this embodiment) clamps 144, to hold the later mentioned frame, are disposed at intervals in the circumferential direction.

The spinner table 140 includes a motor (not illustrated), which rotates the spinner table 140 around the rotation shaft line which extends in the Z axis direction passing through the center of the spinner table 140. Further, the spinner table 140 also includes an elevating portion (not illustrated) which moves (raises) the spinner table 140 in the Z axis direction, between a raised position to set the workpiece on the spinner table 140, and a lowered position to clean the workpiece held on the spinner table 140. The elevating portion may be an air-driven actuator or a ball screw type actuator, for example.

### Cleaning Portion and Drying Portion of Cleaning Unit 138

Although this is not illustrated, the cleaning portion includes a nozzle which is disposed adjacent to the spinner table 140, and a cleaning fluid supply source which supplies cleaning fluid to the nozzle. The drying portion includes a nozzle disposed adjacent to the spinner table 140, and a compressed air supply source which supplies compressed air to the nozzle.

### Workpiece

FIG. 8 is a view of a disk-shaped wafer 146 which is a workpiece to be processed using the abovementioned processing apparatus 2. A wafer 146 is formed of such semiconductor material as silicon and silicon carbide. On a front face 146a of the wafer 146, a chip region 150 where chips 148 (e.g. ICs) are formed, and an outer peripheral surplus region 152 which surrounds the chip region 150, are created. The chip region 150 is sectioned by division lines 154, and a chip 148 is formed in each region sectioned by the division lines 154. In this embodiment, a plurality of rectangular regions are formed in lattice shapes by the division lines 154, however it is not limited that division lines form the lattice shapes, but hexagonal regions, for example, may be formed by the division lines. In FIG. 8, a ring-shaped boundary line 156 between the chip region 150 and the outer peripheral surplus region 152 is indicated by a two-dot chain line for convenience, but the line indicating the boundary line 156 does not actually exist.

A circular protective member 158 is disposed on a rear face 146b of the wafer 146. The diameter of the protective member 158 may be the same as the diameter of the wafer 146, but may also be slightly larger than the diameter of the wafer 146. The protective member 158 may be an adhesive tape or a thermocompression bonding tape. The thermocompression bonding tape is a thermoplastic synthetic resin (e.g. polyolefin resin) not containing adhesive, and has adhesive force when softened or melt by heating to a temperature close to the melting point. The wafer 146 illustrated in FIG. 8 includes the protective member 158, but the wafer 146 may not include the protective member 158.

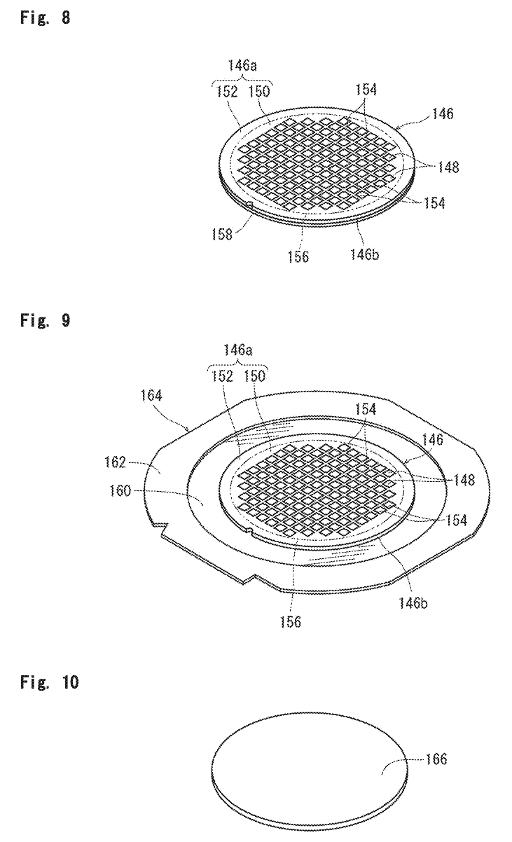

As illustrated in FIG. 9, the workpiece may be a frame unit 164 where the wafer 146 is supported by an annular frame 162 via a circular protective member 160. In the frame unit 164, the rear face 146b of the wafer 146 is attached to the protective member 160, and the outer periphery of the protective member 160 is attached to the inner periphery of the frame 162. The protective member 160 may be an adhesive tape or thermocompression bonding tape.

### Reinforcing Member 166

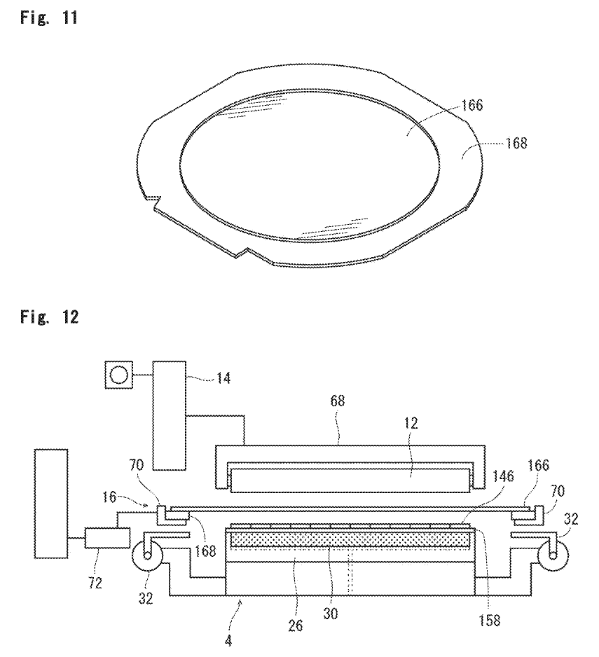

FIG. 10 is a view of a disk-shaped reinforcing member 166 which is attached to the wafer 146 processed by the processing unit 6. The reinforcing member 166 may be made of glass or synthetic resin. In the case where the reinforcing member 166 is made of glass, an adhesive or glue is applied to one side of the reinforcing member 166. In the case where the reinforcing member 166 is made of synthetic resin, an adhesive tape or thermocompression bonding tape may be used. In the case where the reinforcing member 166 is made of synthetic resin, the outer periphery of the reinforcing member 166 may be attached to an annular frame 168 as illustrated in FIG. 11.

In the case where the reinforcing member 166 is a synthetic resin tape (adhesive tape or thermocompression bonding tape), a tape roll, where tape is wound in a cylindrical shape, may be set in a tape dispenser unit (not illustrated) of the processing apparatus 2, so that the tape drawn out of the tape roll is attached to the processed wafer 146 by the attaching roller 12. In this case, the tape dispenser unit functions as the reinforcing member supporting portion which supports the reinforcing member 166 in a state where the principal surface of the reinforcing member 166 faces the holding surface of the holding portion 4.

### Chip Manufacturing Method

A chip manufacturing method will be described next. Here a method for manufacturing the chip 148 by dividing the wafer 146 into individual chips 148 along the division lines 154, using the abovementioned processing apparatus 2, will be described.

### Setting

To manufacture individual chips 148 from the wafer 146, setting is performed first, where the wafer 146 and the reinforcing member 166 are set at the processing apparatus 2. In the setting, a container housing a plurality of wafers 146 and a container housing a plurality of reinforcing members 166 are stacked and mounted on the upper face of the mounting table 106 at a predetermined position. The wafer 146 may not be supported by the frame 162 and include the protective member 158 (see FIG. 8), or may be configured as a frame unit 164 supported by the frame 162 (see FIG. 9). The reinforcing member 166 may be the reinforcing member 166 alone (see FIG. 10), or may be attached to the frame 168 (see FIG. 11). With regard to the reinforcing member 166, in a case where the reinforcing member 166 is a synthetic resin tape, the abovementioned tape roll may be set in a tape dispenser unit of the processing apparatus 2.

### Holding

After the setting, the holding is performed, where the wafer 146 is conveyed from the container to the chuck table 26 of the holding portion 4, and the wafer 146 is held on the chuck table 26.

### Holding for Wafer 146 Supported by Frame 162

In a case of performing the holding for the wafer 146 supported by the frame 162 (frame unit 164), the ends of the frame unit 164 inside the container are clamped between the pair of holding pieces 128 of the first conveying portion 116 illustrated in FIG. 7. Then the pair of holding pieces 128 clamping the ends of the frame unit 164 are moved in the Y axis direction, and the frame unit 164 is drawn out of the container. The frame unit 164 is then placed on the supporting rails 70 of the reinforcing member supporting portion 16 such that the protective member 160 faces down. Here the supporting rails 70 are placed in advance at positions where the frame unit 164 can be received. Then the arm 88 of the first receiving portion 82 is moved so that the suction pads 90 of the first receiving portion 82 contact with the frame unit 164. Then the suction force is generated on the suction pad 90, so as to hold the frame unit 164 by suction on the suction pads 90. Then the arm 88 of the first receiving portion 82 is raised, and the interval between the supporting rails 70 is increased. Then the arm 88 of the first receiving portion 82 is lowered, and the frame unit 164 is placed on the upper face of the chuck table 26. Here the chuck table 26 is placed in advance at a position where the frame unit 164 can be received. Then the suction force is generated on the suction chuck 30 of the chuck table 26, so as to hold the protective member 160 side of the wafer 146 by suction on the holding surface of the holding portion 4. Further, the frame 162 is clamped by the clamps 32 and fixed thereby. Then the suction force of the suction pad 90 of the first receiving portion 82 is released, and the frame unit 164 is transferred from the first receiving portion 82 to the holding portion 4.

### Holding for Wafer 146 Not Supported by Frame 162

In a case of performing the holding for the wafer 146 not supported by the frame 162, the wafer 146 inside the container is held by suction first using the conveying holding portion 136 of the second conveying portion 118 illustrated in FIG. 4. Then the conveying holding portion 136 holding the wafer 146 by suction is moved in the Y axis direction. Then the wafer 146 is drawn out of the container and the wafer 146 is placed on the upper face of the chuck table 26 such that the protective member 158 faces down. Here the chuck table 26 is placed in advance at a position where the frame unit 164 can be received. Then the suction force is generated on the suction chuck 30 of the chuck table 26, so as to hold the protective member 158 side of the wafer 146 by suction on the holding surface of the holding portion 4. Then the suction force of the conveying holding portion 136 of the second conveying portion 118 is released, and the wafer 146 is transferred from the second conveying portion 118 to the holding portion 4.

In the example described here, the wafer 146 is conveyed from the container to the chuck table 26 of the holding portion 4 using the first conveying portion 116 or the second conveying portion 118, but the operator may manually place the wafer 146 on the chuck table 26 without using the first conveying portion 116 or the second conveying portion 118.

### Dividing Start Point Forming

After the holding, the dividing start point forming is performed, where the dividing start point is formed along the division lines 154 on the wafer 146 while holding the wafer 146 on the holding portion 4. In the dividing start point forming, a case where the processing unit 6 is a cutting unit and a case where the processing unit 6 is a laser beam applying unit will be described in sequence.

### Forming Dividing Start Point by Cutting Unit

The dividing start point forming in the case where the processing unit 6 is the cutting unit will be described first. In the dividing start point forming, an imaging portion (not illustrated) of the processing apparatus 2 captures an image of the wafer 146 from above. Then based on the image of the wafer 146 captured by the imaging portion, the division lines 154 are aligned with the X axis direction. Then the cutting blade 44 is placed above the division line 154 aligned in the X axis direction. Then the edge of the cutting blade 44, which is rotating at high-speed, is allowed to enter from the front face 146a of the wafer 146 down to a predetermined depth at the division lines 154 aligned in the X axis direction. Also while cutting water is supplied to a portion where the edge of the cutting blade 44 enters, using the cutting water nozzle 46, the first moving portion 8 feeds the chuck table 26 in the X axis direction for processing. Thereby for the dividing start point, a half cut groove at a predetermined depth can be formed on the front face 146a of the wafer 146 along the division line 154.

Then the second moving portion 10 index-feeds the cutting blade 44 in the Y axis direction for the amount of the interval of the division lines 154 in the Y axis direction. By alternately repeating the forming the half cut groove and index-feeding, the half cut groove is formed for all the division lines 154 aligned in the X axis direction. Then the chuck table 26 is rotated 90°, and the forming of the half cut groove and index-feeding are alternately repeated. Thereby the half cut grooves are formed along all the division lines 154 orthogonally intersecting with the half cut grooves already formed. Thus the latticed half cut grooves are formed on the front face 146a of the wafer 146 along the latticed division lines 154.

### Forming Dividing Start Point by Laser Beam Applying Unit

The dividing start point forming in the case where the processing unit 6 is the laser beam applying unit will be described next. In this case as well, the imaging portion (not illustrated) of the processing apparatus 2 captures an image of the wafer 146 from above. Then based on the image of the wafer 146 captured by the imaging portion, the division lines 154 are aligned in the X axis direction. Then the laser beam is aimed at the division line 154 aligned with the X axis direction, and the condensing point of the laser beam is positioned inside the wafer 146. Then while a laser beam having a wavelength that is transmissive to the wafer 146 is applied to the wafer 146, the first moving portion 8 feeds the chuck table 26 in the X axis direction for processing. Thereby a modified layer can be formed inside the wafer 146 as the dividing start point, along the division lines 154. Then applying the laser beam and index-feeding are alternately repeated, and just like the case of forming the half cut groove, the latticed modified layer is formed inside the wafer 146 along the latticed division lines 154.

In the case where the processing unit 6 is the laser beam applying unit, the half cut grooves having a predetermined depth may be formed on the front face 146a of the wafer 146 as the dividing start point, by performing ablation processing on the front face 146a of the wafer 146. In the case of forming the half cut grooves by ablation processing, the front face 146a of the wafer 146 is coated in advance with a protective film (not illustrated) of water soluble resin or the like, so that debris generated during the ablation processing does not adhere to the front face 146a of the wafer 146. Then the condensing point of the laser beam having a wavelength that is absorbable by the wafer 146 is placed on the front face 146a of the wafer 146, and the laser beam is applied to the wafer 146. Thereby the half cut grooves having a predetermined depth can be formed as the dividing start point on the front face 146a of the wafer 146.

### Cleaning and Drying

After the dividing start point forming, the cleaning and drying is performed, where the wafer 146 is cleaned with a cleaning fluid and dried with compressed air. This cleaning and drying may be omitted if the processing unit 6 is the laser beam applying unit, and the modified layer used for the dividing start point is formed inside the wafer 146 by laser processing. This is because the modified layer is formed inside the wafer 146, and processing chips are not generated very much during processing.

In the case where the processing unit 6 is a cutting unit and the half cut groove used for the dividing start point is formed on the front face 146a of the wafer 146 by cutting processing, the cleaning and drying process can be performed on the wafer 146 in the state of being held on the holding portion 4. In this case, the cleaning fluid is supplied from the nozzle of the cleaning portion of the processing unit 6 to the wafer 146 held on the holding portion 4. Thereby the wafer 146 is cleaned and the chips generated during the cutting processing are removed from the wafer 146. Once the chips are removed, the compressed air is supplied from the nozzle of the drying portion of the processing unit 6 to the wafer 146 held on the holding portion 4. Thereby the cleaning fluid is removed from the wafer 146 and the wafer 146 is dried.

In the case where the processing unit 6 is the laser beam applying unit and the half cut groove used for the dividing start point is formed on the front face 146a of the wafer 146 by the ablation processing, the cleaning and drying is performed by the cleaning unit 138.

In this case, the wafer 146 is conveyed from the holding portion 4 to the cleaning unit 138. First the holding portion 4 is moved by the first moving portion 8, and the position of the holding portion 4 in the X axis direction is aligned with the position of the cleaning unit 138 in the X axis direction. Then the arm 92 of the second receiving portion 86 illustrated in FIG. 4 is moved by the arm moving portion 96, and the suction pads 94 of the second receiving portion 86 are contacted with the front face 146a of the wafer 146 held on the holding portion 4 (or the upper face of the frame 162 in the case of the frame unit 164). Then the suction force is generated on the suction pads 94, so as to hold the wafer 146 or the frame 162 by the suction pads 94 by suction. Then the suction force of the holding portion 4 is released, and the wafer 146 is transferred from the holding portion 4 to the second receiving portion 86. Then the arm 92 of the second receiving portion 86 is moved and the lower face of the wafer 146 is contacted with the upper face of the spinner table 140 of the cleaning unit 138. Then the suction force is generated on the suction chuck 142 of the spinner table 140, and the lower face of the wafer 146 is held on the spinner table 140 by suction. In the case of the frame unit 164, the frame 162 is fixed by clamping with clamps 144 of the cleaning unit 138. Then the suction force of the suction pads 94 of the second receiving portion 86 is released, and the wafer 146 is transferred from the second receiving portion 86 to the cleaning unit 138.

Once the wafer 146 is conveyed to the cleaning unit 138, the spinner table 140 is placed at the lowered position. Then while rotating the spinner table 140, the cleaning fluid is supplied from the nozzle of the cleaning portion to the wafer 146. Thereby the wafer 146 is cleaned, and the protective film and debris are removed from the wafer 146. Then while rotating the spinner table 140, compressed air is supplied from the nozzle of the drying portion to the wafer 146. Thereby the cleaning fluid is removed from the wafer 146, and the wafer 146 is dried. Once the wafer 146 is dried, the second receiving portion 86 receives the wafer 146 from the cleaning unit 138, and conveys the wafer 146 to the holding portion 4. Then the wafer 146 is held on the holding portion 4.

### Reinforcing

After the cleaning and drying, the reinforcing is performed, where the reinforcing member 166 is fixed to the exposed surface of the wafer 146 held on the holding portion 4. If the rear face 146b of the wafer 146, on which the protective member 158 or 160 is fixed, is a first surface, the reinforcing member 166 is fixed to a second surface (front face 146a) on the opposite side of the first surface (rear face 146b) of the wafer 146.

In the reinforcing, the reinforcing member 166 to be fixed to the wafer 146 and the wafer 146 held on the holding portion 4 are placed at predetermined positions, such that the principal surface of the reinforcing member 166 faces the exposed surface (front face 146a) of the wafer 146.

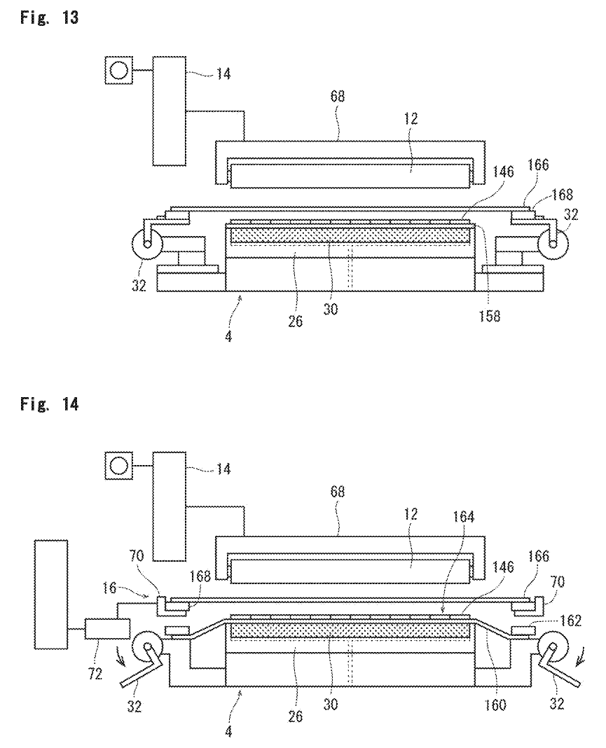

With regard to the reinforcing member 166, in a case where the reinforcing member 166 is supported by the frame 168 and is housed in the container on the mounting table 106, the first conveying portion 116 conveys the reinforcing member 166 from the container on the mounting table 106 to the supporting rails 70 of the reinforcing member supporting portion 16 (see FIG. 12). The reinforcing member 166 may be conveyed not to the supporting rails 70, but to the upper end face of the clamps 32 in the holding position functioning as the reinforcing member supporting portion (see FIG. 13). In a case where the reinforcing member 166 is not supported by the frame 168 and housed in the container on the mounting table 106, on the other hand, the second conveying portion 118 conveys the reinforcing member 166 from the container to the supporting rails 70. In this case as well, the reinforcing member 166 may be conveyed not to the supporting rails 70, but to the upper end face of the clamps 32 in the holding position. The operator may manually place the reinforcing member 166 on the supporting rails 70 or the clamps 32. If the tape used for the reinforcing member 166 is set in the tape dispensing unit in the state of the tape roll, the tape used for the reinforcing member 166 is dispensed from the tape roll to a predetermined position.

For the wafer 146 held on the holding portion 4, the first moving portion 8 moves the holding portion 4 and places the exposed surface of the wafer 146 below the principal surface of the reinforcing member 166, as illustrated in FIG. 12. Conversely, the principal surface of the reinforcing member 166 may be placed above the exposed surface of the wafer 146 after placing the wafer 146 held on the holding portion 4 at a predetermined position. In other words, it does not matter whether the reinforcing member 166 or the wafer 146 is placed at the predetermined position first. In a state where the reinforcing member 166 and the wafer 146 are placed at the predetermined positions, the principal surface of the reinforcing member 166 and the exposed surface of the wafer 146 are not in contact, and a slight gap exists between the principal surface of the reinforcing member 166 and the exposed surface of the wafer 146. The gap between the principal surface of the reinforcing member 166 and the exposed surface of the wafer 146 may be created such that the principal surface of the reinforcing member 166 can reach the exposed surface of the wafer 146 when the reinforcing member 166 is pressed toward the wafer 146 by the attaching roller 12.

Once the reinforcing member 166 and the wafer 146 are placed at the predetermined positions, the reinforcing member 166 and the wafer 146 are integrated by the attaching roller 12. Here the actuator 84 of the reversing portion 80 reverses the bracket 68 from the state illustrated in FIG. 4, and the attaching roller 12 is placed below the first receiving portion 82. If the reinforcing member 166 is a thermocompression sheet, the outer peripheral surface of the attaching roller 12 is heated to a temperature near the melting point of the thermocompression sheet. Then the third moving portion 14 lowers the attaching roller 12 and the attaching roller 12 presses the reinforcing member 166 to the exposed surface (front face 146a) of the wafer 146. Then the third moving portion 14 moves the attaching roller 12 in the Y axis direction. Thereby a reinforcing unit 170, where the reinforcing member 166 supported by the reinforcing member supporting portion 16 and the wafer 146 (workpiece) held on the holding portion 4 are integrated, is generated.

In this embodiment, in the case where the half cut grooves used as the dividing start point are formed by the cutting processing, and in the case where the modified layer used for the dividing start point are formed by the laser processing, the reinforcing can be performed after the dividing start point forming, in a state of holding the wafer 146 at the holding portion 4. In other words, in this embodiment, the reinforcing unit 170, where the processed wafer 146 and the reinforcing member 166 are integrated, can be generated without moving the processed wafer 146 from the holding portion 4. This means that damage to the wafer 146 can be prevented when the wafer 146 is processed by the processing apparatus 2 and the processed wafer 146 is then conveyed to a processing apparatus other than the processing apparatus 2.

In the case of forming the half cut grooves used as the dividing start point by laser processing (ablation processing) as well, the reinforcing unit 170 can be generated before conveying the processed wafer 146 to a processing apparatus other than the processing apparatus 2. This means that damage to the wafer 146 can be prevented when the wafer 146 is processed by the processing apparatus 2 and the processed wafer 146 is conveyed to a processing apparatus other than the processing apparatus 2. In the case of forming the half cut grooves by ablation processing, the processed wafer 146 is conveyed inside the processing apparatus 2 (between the holding portion 4 and the cleaning unit 138) before generating the reinforcing unit 170, but, as to the conveyance of the wafer 146 inside the processing apparatus 2, the risk of damage to the wafer 146 is less than the case of conveying the wafer 146 between the processing apparatus 2 and another processing apparatus (normally the operator manually conveys the container housing the wafer 146). Therefore, it is preferable to generate the reinforcing unit 170 before conveying the wafer 146 to a processing apparatus other than the processing apparatus 2.

In the example described above, the reinforcing member 166 is fixed to the wafer 146 not supported by the frame 162, but the reinforcing member 166 may be fixed to the wafer 146 in the frame unit 164, as illustrated in FIGS. 14 and 15. FIG. 14 is an example where the reinforcing member 166 is supported by the supporting rails 70. As illustrated in FIG. 14, to fix the reinforcing member 166 to the wafer 146 in the frame unit 164, fixing of the frame 162 by the clamps 32 is released in advance before placing the frame unit 164 held on the holding portion 4 below the reinforcing member 166. FIG. 15 is an example where the reinforcing member 166 is supported by the clamps 32. As illustrated in FIGS. 15 or 13, in the case where the reinforcing member 166 is supported by the clamps 32, the clamps 32 have been configured to be slidable in the diameter direction of the chuck table 26. After the reinforcing unit 170 is generated, the clamps 32 are moved to the outer side in the diameter direction of the chuck table 26, away from the reinforcing unit 170, by the air-driven actuator or the like. The reinforcing member 166 fixed to the wafer 146 of the frame unit 164 may be a reinforcing member 166 supported by the frame 168, or a reinforcing member 166 not supported by the frame 168, or may be a tape dispensed from the tape roll.

### Housing

After the reinforcing, housing is performed, where the reinforcing unit 170 is housed in a container on the mounting table 106. In the housing, the reinforcing unit 170 may be housed in the container in a state where the reinforcing member 166 is placed above the wafer 146, but in order to peel off the protective member 158 or 160 (hereafter may be referred to as “protective member 158 or the like”) from the wafer 146 after the housing, it is preferable to house the reinforcing unit 170 in a state where the protective member 158 or the like is placed above the wafer 146. Therefore, in the example of the housing which will be described in this embodiment, the reinforcing unit 170 is reversed, and the protective member 158 or the like is placed above the wafer 146 first, then the reinforcing unit 170 is housed in the container.

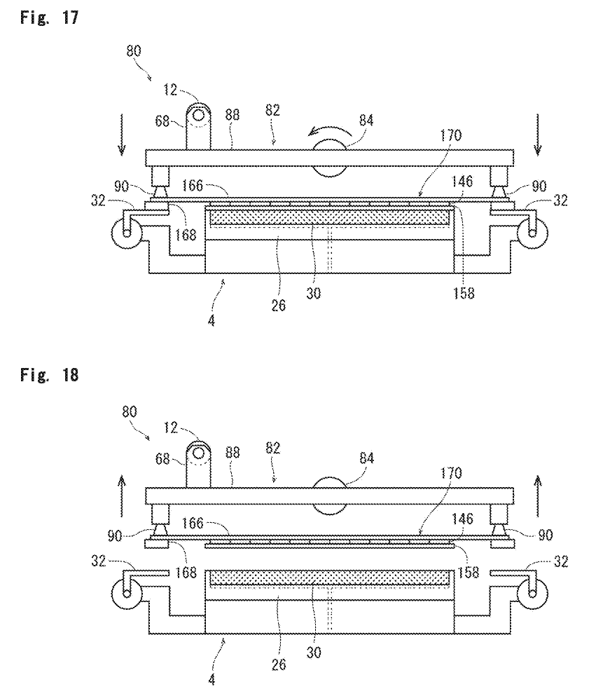

In the housing, the reinforcing unit 170 is transferred from the holding portion 4 to the first receiving portion 82 first. Here as illustrated in FIG. 16, the attaching roller 12 is raised so that the attaching roller 12 is separated from the reinforcing unit 170. In the case where the reinforcing member 166 is supported by the supporting rails 70, the interval between the supporting rails 70 is increased, and the supporting rails 70 are separated from the holding portion 4. Then the actuator 84 of the reversing portion 80 is activated, so that, as illustrated in FIG. 17, the suction pads 90 of the first receiving portion 82 face the reinforcing unit 170, and the first receiving portion 82 is lowered, so that the suction pads 90 contact with the reinforcing unit 170. Then the suction force is generated on the suction pads 90, and the reinforcing unit 170 is held on the suction pads 90 by suction. Then the suction force on the holding portion 4 is released, so that the reinforcing unit 170 is transferred from the holding portion 4 to the first receiving portion 82.

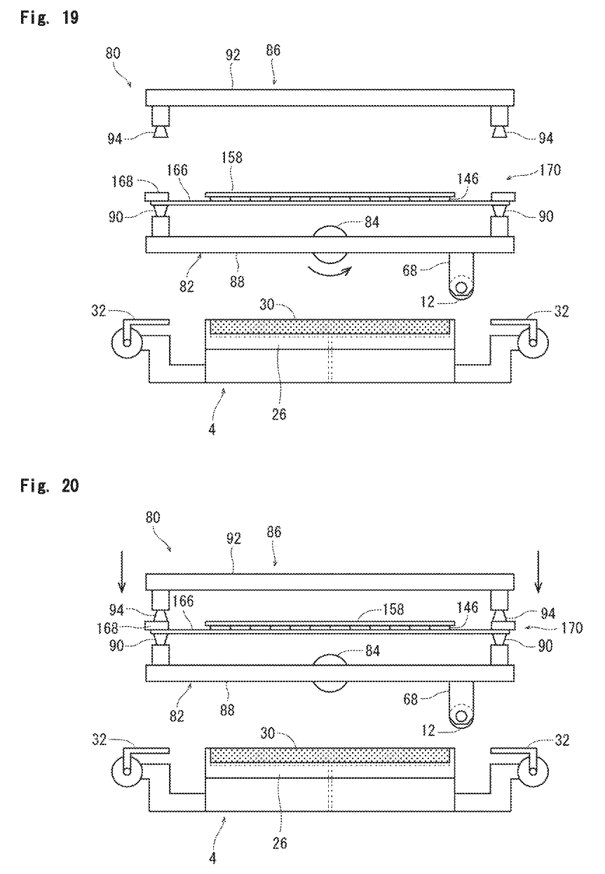

Once the reinforcing unit 170 is transferred from the holding portion 4 to the first receiving portion 82, the reinforcing unit 170 is transferred from the first receiving portion 82 to the second receiving portion 86. Here as illustrated in FIG. 18, the first receiving portion 82 holding the reinforcing unit 170 by suction is raised first. Then the actuator 84 of the reversing portion 80 is activated, so that the reinforcing unit 170 is placed above the first receiving portion 82 as illustrated in FIG. 19. Then the arm 92 of the second receiving portion 86 is placed above the reinforcing unit 170. Then as illustrated in FIG. 20, the arm 92 of the second receiving portion 86 is lowered, so that the suction pads 94 of the second receiving portion 86 contact with the reinforcing unit 170. Then the suction force is generated on the suction pads 94, and the reinforcing unit 170 is held on the suction pads 94 by suction. Then the suction force on the suction pads 90 of the first receiving portion 82 is released, so that the reinforcing unit 170 is transferred from the first receiving portion 82 to the second receiving portion 86.

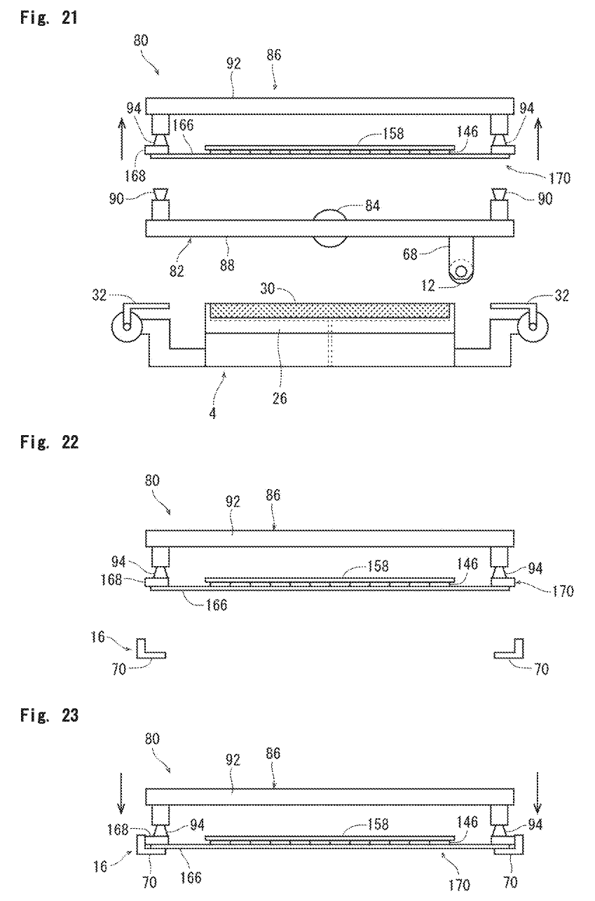

Once the reinforcing unit 170 is transferred from the first receiving portion 82 to the second receiving portion 86, the reinforcing unit 170 is transferred from the second receiving portion 86 to the supporting rails 70 of the reinforcing member supporting portion 16. Here as illustrated in FIG. 21, the second receiving portion 86, holding the reinforcing unit 170 by suction, is raised first. Then the first receiving portion 82 is separated from the spot directly below the reinforcing unit 170. Further, as illustrated in FIG. 22, the pair of supporting rails 70 are placed at a position where the reinforcing unit 170 can be received. Then as illustrated in FIG. 23, the arm 92 of the second receiving portion 86 is lowered so that the reinforcing unit 170 is placed on the supporting rails 70. Then the suction force on the suction pads 94 of the second receiving portion 86 is released, so that the reinforcing unit 170 is transferred from the second receiving portion 86 to the supporting rails 70. Then the second receiving portion 86 is separated from the reinforcing unit 170.

Once the reinforcing unit 170 is transferred from the second receiving portion 86 to the supporting rails 70 of the reinforcing member supporting portion 16, the reinforcing unit 170 is conveyed from the supporting rails 70 to the container. The reinforcing unit 170 can be conveyed from the supporting rails 70 to the container using the first conveying portion 116 or the second conveying portion 118.

### Separating

After the housing, separating is performed, where the protective member 158 or 160 is separated from the wafer 146. In the separating, the protective member 158 is separated from the wafer 146 if the wafer 146 is not supported by the frame 162. The protective member 158 may be manually separated by the operator, or may be separated using an approximate separating apparatus (not illustrated). If the wafer 146 is supported by the frame 162 (frame unit 164), the protective member 160 and the frame 162 are separated from the wafer 146. The protective member 160 and the frame 162 may also be manually separated by the operator, or may be separated using an appropriate separating apparatus (not illustrated).

### Dividing

After the separating step, dividing is performed, where the wafer 146 is divided along the division lines 154.

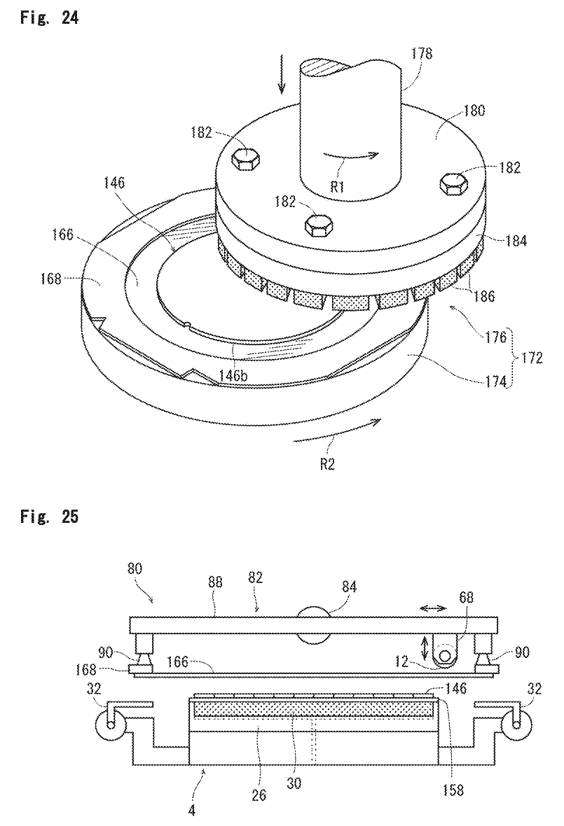

The dividing can be performed using a grinding apparatus 172 illustrated in FIG. 24, for example. The grinding apparatus 172 includes: a chuck table 174 which holds the wafer 146 by suction; and a grinding portion 176 which grinds the wafer 146 held on the chuck table 174 by suction. The grinding portion 176 includes: a spindle 178 which extends in the vertical direction; and a disc-shaped wheel mount 180 which is fixed to the lower end of the spindle 178. An annular grinding wheel 184 is fastened to the lower face of the wheel mount 180 by bolts 182. A plurality of grinding stones 186 are fixed at the outer periphery portion of the lower face of the grinding wheel 184 at intervals in the circumferential direction.

In the dividing, the wafer 146 is held on the upper face of the chuck table 174 by suction, such that the rear face 146b of the wafer 146 faces up. Then the spindle 178 is rotated in a direction indicated by the arrow R1. The chuck table 174 is rotated in a direction indicated by the arrow R2. Then the spindle 178 is lowered such that the grinding stones 186 are contacted with the rear face 146b of the wafer 146, and at the same time, grinding water is supplied to the portion where the grinding stones 186 are contacted with the rear face 146b. Then the spindle 178 is lowered at a predetermined grinding feed speed, and the rear face 146b of the wafer 146 is ground. Thereby the half cut grooves used as the dividing start point are exposed on the rear face 146b of the wafer 146, and the wafer 146 can be divided into individual chips 148 along the division lines 154. In the case where the modified layer, used as the dividing start point, is formed inside the wafer 146, a crack extends from the modified layer in the thickness direction of the wafer 146 by the pressing force that is applied when the wafer 146 is ground. As a result, the wafer 146 is divided into individual chips 148 along the division lines 154.

In the case where the half cut grooves, used as the dividing start point, are formed on the front face 146a of the wafer 146, the dividing may be performed using the abovementioned processing apparatus 2. In the case of performing the dividing using the processing apparatus 2, the cutting processing or ablation processing is performed in advance on the rear face 146b of the wafer 146 along the half cut grooves, whereby the wafer 146 can be divided into individual chips 148 along the division lines 154.

As described above, in this embodiment, the reinforcing unit 170 is generated by integrating the reinforcing member 166 supported by the reinforcing member supporting portion 16 and the processed wafer 146 held on the holding portion 4, using the attaching roller 12. Therefore, after the wafer 146 is processed in the processing apparatus 2, damage to the wafer 146 is prevented when the processed wafer 146 is transported to a processing apparatus other than the processing apparatus 2.

The present disclosure is not limited to the embodiment described above, but may be modified in various ways. For example, the attaching roller 12 is fixed to the bracket 68 in this embodiment, but may be supported movably in the Y axis direction and the Z axis direction on the lower face side (suction pads 90 side) of the arm 88 of the first receiving portion 82, as illustrated in FIG. 25. In this case, a first roller moving portion which moves the attaching roller 12 in the Y axis direction, and a second roller moving portion which moves the attaching roller 12 in the Z axis direction, are attached to the arm 88 of the first receiving portion 82. The first and second roller moving portions may be air-driven actuators or ball screw type actuators, for example.

### REFERENCE SIGNS LIST

2 Processing apparatus

4 Holding portion

6 Processing unit

8 First moving portion

10 Second moving portion

12 Attaching roller

14 Third moving portion

16 Reinforcing member supporting portion

18 Control portion

42 Spindle

44 Cutting blade

80 Reversing portion

98 Mounting portion

100 Conveying portion

146 Wafer (workpiece)

146a front face of wafer

146b Rear face of wafer

148 Chip

150 Chip region

154 Division line

158 Protective member

160 Protective member

166 Reinforcing member

170 Reinforcing unit

What is claimed is:

1. A processing apparatus for processing a plate-like workpiece, the apparatus comprising:
a holding portion including a holding surface to hold the workpiece;
a processing unit configured to process the workpiece held on the holding portion;
a first moving portion configured to relatively move a processing point of the processing unit and the holding portion in a first direction along the holding surface;
a second moving portion configured to relatively move the processing point of the processing unit and the holding portion in a second direction that intersects the first direction and is along the holding surface;
an attaching roller extending along the holding surface;
a third moving portion configured to relatively move the attaching roller and the holding portion;
a reinforcing member supporting portion configured to support a reinforcing member such that a principal surface of the reinforcing member faces the holding surface of the holding portion; and
a control portion configured to control at least the third moving portion and to generate a reinforcing unit in which the reinforcing member supported by the reinforcing member supporting portion and the workpiece held on the holding portion are integrated by the attaching roller.

2. The processing apparatus of claim 1, further comprising a reversing portion configured to reverse the workpiece, the reinforcing member, or the reinforcing unit.

3. The processing apparatus of claim 2, further comprising:
a mounting portion on which a container for housing the workpiece, the reinforcing member or the reinforcing unit is mounted; and
a conveying portion configured to convey the workpiece, the reinforcing member or the reinforcing unit between the mounting portion and the holding portion.

4. The processing apparatus of claim 3, wherein
the processing unit is a laser beam applying unit including a laser oscillator for oscillating a laser beam, and a condensing lens for condensing the laser beam oscillated by the laser oscillator.

5. The processing apparatus of claim 1, wherein
the processing unit is a cutting unit including a spindle configured to be rotatable around a rotation shaft line, and a cutting blade attached to the spindle,
the processing unit further comprising:
a cleaning portion configured to supply cleaning fluid to the workpiece held on the holding portion; and
a drying portion configured to supply compressed air to the workpiece held on the holding portion.

6. A chip manufacturing method for manufacturing chips by dividing a plate-like workpiece, where chip regions in which chips are formed are included and division lines for sectioning the chip regions are set, into individual chips along the division lines, the method comprising:
forming a dividing start point along the division line on the workpiece while holding the workpiece on a holding portion;
implementing reinforcement by fixing a reinforcing member to an exposed surface of the workpiece held on the holding portion after the forming of a dividing start point; and
dividing the workpiece along the division line after the implementing of reinforcement.

7. The chip manufacturing method of claim 6, wherein
a protective member is fixed to a first face of the workpiece,
in the implementing of reinforcement, the reinforcing member is fixed to a second face of the workpiece, the second face being on an opposite side to the first face,
the method further comprising separating the protective member from the workpiece after the implementing of reinforcement and before the dividing of the workpiece.

8. A processing method for processing a plate-like workpiece, the method comprising:
forming a dividing start point along a division line on the workpiece while holding the workpiece on a holding portion; and
implementing reinforcement by fixing a reinforcing member to an exposed surface of the workpiece held on the holding portion after the forming of a dividing start point.

9. The processing apparatus of claim 1, wherein
the processing unit is a laser beam applying unit including a laser oscillator for oscillating a laser beam, and a condensing lens for condensing the laser beam oscillated by the laser oscillator.

10. The processing apparatus of claim 2, wherein
the processing unit is a laser beam applying unit including a laser oscillator for oscillating a laser beam, and a condensing lens for condensing the laser beam oscillated by the laser oscillator.

11. The processing apparatus of claim 2, wherein
the processing unit is a cutting unit including a spindle configured to be rotatable around a rotation shaft line, and a cutting blade attached to the spindle,
the processing unit further comprising:
a cleaning portion configured to supply cleaning fluid to the workpiece held on the holding portion; and
a drying portion configured to supply compressed air to the workpiece held on the holding portion.

12. The processing apparatus of claim 3, wherein
the processing unit is a cutting unit including a spindle configured to be rotatable around a rotation shaft line, and a cutting blade attached to the spindle,
the processing unit further comprising:
a cleaning portion configured to supply cleaning fluid to the workpiece held on the holding portion; and
a drying portion configured to supply compressed air to the workpiece held on the holding portion.
